(19) United States
(12) Patent Application Publication
(10) Pub. No.: US 2025/0241020 A1
(43) Pub. Date: Jul. 24, 2025

(54) SCHOTTKY DIODE AND SEMICONDUCTOR INTEGRATED CIRCUIT DEVICE INCLUDING THE SAME

(71) Applicant: DB HiTek Co., Ltd., Seoul (KR)

(72) Inventor: Kyu Ok LEE, Suwon-si (KR)

(73) Assignee: DB HiTek Co., Ltd., Seoul (KR)

(21) Appl. No.: 18/618,498

(22) Filed: Mar. 27, 2024

(30) Foreign Application Priority Data
Jan. 23, 2024 (KR) 10-2024-0010244

(51) Int. Cl. H01L 29/06; H01L 21/762; H01L 27/02; H01L 29/40; H01L 29/872

(52) U.S. Cl. CPC H10D 62/106; H01L 21/76224; H10D 8/60; H10D 64/112; H10D 89/10

(57) ABSTRACT

A semiconductor integrated circuit device comprising: a substrate; a buried layer disposed on one side of the substrate; a well including a semiconductor region disposed on one side of the buried layer; and a Schottky diode portion disposed on one side of the well, wherein the Schottky diode portion comprises an anode, a guard ring electrically connected with the anode, and a poly field plate electrically connected with the anode and the guard ring, and the guard ring comprises at least one slit configured to block a flow of current.

### CROSS-REFERENCE TO RELATED APPLICATION

This application claims priority under 35 U.S.C § 119 to Korean Patent Application No. 10-2024-0010244 filed on Jan. 23, 2024, in the Korean Intellectual Property Office, the entire contents of which are hereby incorporated by reference.

### TECHNICAL FIELD

The disclosure relates to a Schottky diode and a semiconductor integrated circuit device including the same.

### BACKGROUND

The contents set forth in this section merely provide background information on the present embodiments and do not constitute prior art.

A Schottky diode (Schottky barrier diode) is a diode that utilizes the rectifying action of a barrier (Schottky barrier) that forms at the contact surface of a metal and a semiconductor.

A Schottky diode has a lower turn-on voltage compared to a PN junction diode, and thus has a low voltage drop characteristic in the forward state (forward operating condition) and is advantageous for high-speed operation.

However, Schottky diodes have the drawbacks of having a lower BV (breakdown voltage) characteristic and a higher leakage characteristic compared to PN junction diodes in the reverse state.

Accordingly, in a general case, lateral Schottky diodes have been developed in the direction of compensating for the insufficient performance by using P-type guard rings in order to compensate for the drawbacks of these reverse characteristics.

### SUMMARY

An object to be achieved by the present disclosure is to provide a Schottky diode, which can achieve the effect of improving ON-resistance (RON) by reducing the current path in a local area by forming a slit in a guard ring instead of using an existing bar type guard ring, and a semiconductor integrated circuit device including the same.

In addition, an object to be achieved by the present disclosure is to provide a Schottky diode, which can improve a BV characteristic in the reverse state and increase a diode on/off characteristic ratio by minimizing a leakage current by forming a slit in a guard ring, and a semiconductor integrated circuit device including the same.

The objects of the present disclosure are not limited to the objects mentioned above, and other objects and advantages of the present disclosure that have not been mentioned can be understood by the following description and will be more clearly understood by the embodiments of the present disclosure. Further, it will be readily appreciated that the objects and advantages of the present disclosure may be realized by the means set forth in the claims and combinations thereof.

According to some aspects of the disclosure, a semiconductor integrated circuit device comprises, a substrate, a buried layer disposed on one side of the substrate, a well including a semiconductor region disposed on one side of the buried layer, and a Schottky diode portion disposed on one side of the well, wherein the Schottky diode portion comprises an anode, a guard ring electrically connected with the anode, and a poly field plate electrically connected with the anode and the guard ring, and the guard ring comprises at least one slit configured to block a flow of current.

According to some aspects, the slit is formed to penetrate at least one region of the guard ring.

According to some aspects, the guard ring comprises a first guard ring part through a third guard ring part, and the first guard ring part and the third guard ring part are arranged to face each other.

According to some aspects, the slit is formed in at least one of between the first guard ring part and the second guard ring part and between the third guard ring part and the second guard ring part.

According to some aspects, the slit is formed in at least one of between adjacent faces of the first guard ring part and the second guard ring part and between adjacent faces of the third guard ring part and the second guard ring part.

According to some aspects, the slit comprises at least one of a first slit formed between a first face of the first guard ring part and a second face of the second guard ring part and a second slit formed between a third face of the third guard ring part and a fourth face of the second guard ring part, and wherein the first face comprises a face closest to the second guard ring part among a plurality of faces of the first guard ring part, the second face comprises a face closest to the first guard ring part among a plurality of faces of the second guard ring part, the third face comprises a face closest to the second guard ring part among a plurality of faces of the third guard ring part, and the fourth face comprises a face closest to the third guard ring part among the plurality of faces of the second guard ring part.

According to some aspects, the first slit and the second slit are disposed in positions facing each other.

According to some aspects, the slit has a size smaller than a separation distance between a fifth face of the first guard ring part disposed on one side of the first face and a sixth face of the third guard ring part disposed on one side of the third face, and the fifth face and the sixth face are disposed in positions facing each other.

According to some aspects, the size of the slit is 0.2 μm or more and 2 μm or less.

According to some aspects, the Schottky diode portion further comprises: a cathode disposed to surround the anode, the guard ring, and the poly field plate; and an insulator configured to electrically separate the anode and the cathode, and wherein the insulator comprises a shallow trench isolation (STI).

According to some aspects of the disclosure, a Schottky diode portion disposed on one side of a well including a semiconductor region, the Schottky diode portion comprises, an anode, a guard ring electrically connected with the anode; and a poly field plate electrically connected with the anode and the guard ring, wherein the guard ring comprises at least one slit configured to block a flow of current.

According to some aspects, the slit is formed to penetrate at least one region of the guard ring.

According to some aspects, wherein the guard ring comprises a first guard ring part through a third guard ring part, and the first guard ring part and the third guard ring part are arranged to face each other.

According to some aspects, the slit is formed in at least one of between the first guard ring part and the second guard ring part and between the third guard ring part and the second guard ring part.

According to some aspects, the slit is formed in at least one of between adjacent faces of the first guard ring part and the second guard ring part and between adjacent faces of the third guard ring part and the second guard ring part.

According to some aspects, the slit comprises at least one of a first slit formed between a first face of the first guard ring part and a second face of the second guard ring part and a second slit formed between a third face of the third guard ring part and a fourth face of the second guard ring part, and wherein the first face comprises a face closest to the second guard ring part among a plurality of faces of the first guard ring part, the second face comprises a face closest to the first guard ring part among a plurality of faces of the second guard ring part, the third face comprises a face closest to the second guard ring part among a plurality of faces of the third guard ring part, and the fourth face comprises a face closest to the third guard ring part among the plurality of faces of the second guard ring part.

According to some aspects, the first slit and the second slit are disposed in positions facing each other.

According to some aspects, the slit has a size smaller than a separation distance between a fifth face of the first guard ring part disposed on one side of the first face and a sixth face of the third guard ring part disposed on one side of the third face, and the fifth face and the sixth face are disposed in positions facing each other.

According to some aspects, the size of the slit is 0.2 μm or more and 2 μm or less.

According to some aspects, a cathode disposed to surround the anode, the guard ring, and the poly field plate; and an insulator configured to electrically separate the anode and the cathode, and wherein the insulator comprises a shallow trench isolation (STI).

Aspects of the disclosure are not limited to those mentioned above and other objects and advantages of the disclosure that have not been mentioned can be understood by the following description and will be more clearly understood according to embodiments of the disclosure. In addition, it will be readily understood that the objects and advantages of the disclosure can be realized by the means and combinations thereof set forth in the claims.

The Schottky diode and the semiconductor integrated circuit device including the same of the present disclosure can achieve the effect of improving ON-resistance (RON) according to the reduction of the current path in the local area by forming a slit in the guard ring. As a result, the Schottky diode and the semiconductor integrated circuit device including the same of the present disclosure can be expected to have the effect of improving the ON-resistance by 15 to 30% compared to the existing structure.

Further, the Schottky diode and the semiconductor integrated circuit device including the same of the present disclosure can improve the BV characteristic in the reverse state and increase the on/off characteristic ratio by reducing the leakage current by forming a slit in the guard ring.

In addition to the contents described above, specific effects of the present disclosure will be described together while describing the following specific details for carrying out the present disclosure.

### BRIEF DESCRIPTION OF THE DRAWINGS

FIG. 1 is a top view of a semiconductor integrated circuit device in accordance with some embodiments of the present disclosure.

FIG. 2 is a diagram for describing a guard ring in accordance with some embodiments of the present disclosure.

FIGS. 3a and 3b are side views of a semiconductor integrated circuit device in accordance with some embodiments of the present disclosure.

FIG. 4 is a diagram for describing a guard ring in accordance with some other embodiments of the present disclosure.

FIG. 5 is a diagram for describing a guard ring in accordance with yet some other embodiments of the present disclosure.

FIG. 6 is a diagram for describing a guard ring in accordance with yet some other embodiments of the present disclosure.

FIG. 7 is a diagram for describing a guard ring in accordance with yet some other embodiments of the present disclosure.

FIG. 8 is a diagram for describing a guard ring in accordance with yet some other embodiments of the present disclosure.

### DETAILED DESCRIPTION OF THE PREFERRED EMBODIMENTS

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

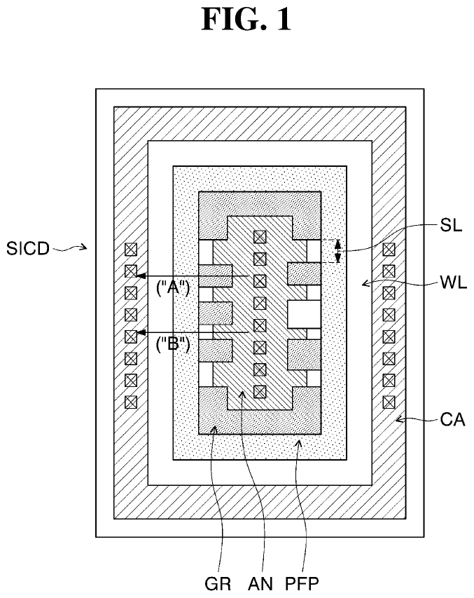

In the following, a Schottky diode and a semiconductor integrated circuit device including the same in accordance with an embodiment of the present disclosure will be described with reference to FIGS. 1 to 8.

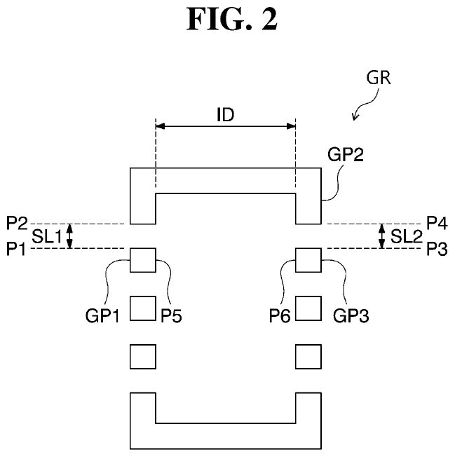

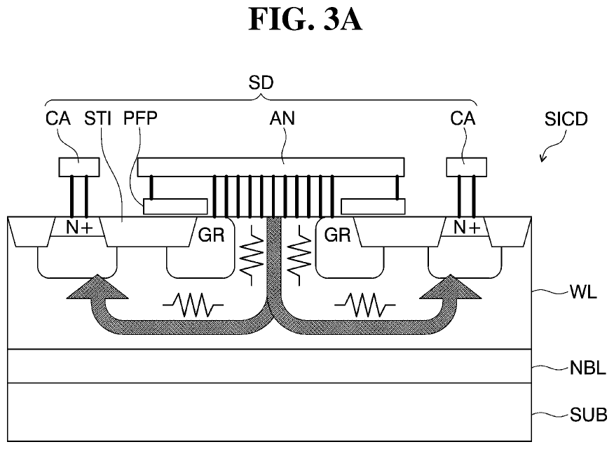

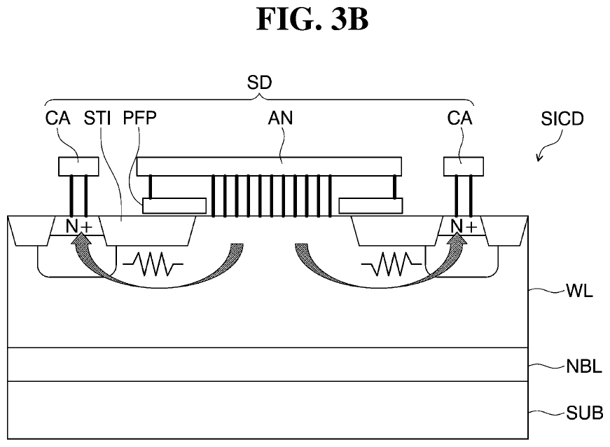

FIG. 1 is a top view of a semiconductor integrated circuit device in accordance with some embodiments of the present disclosure. FIG. 2 is a diagram for describing a guard ring in accordance with some embodiments of the present disclosure. FIGS. 3a and 3b are side views of a semiconductor integrated circuit device in accordance with some embodiments of the present disclosure.

Referring to FIGS. 1 to 3b, a semiconductor integrated circuit device (hereinafter referred to as “SICD”) in accordance with some embodiments of the present disclosure may include a substrate (hereinafter referred to as “SUB”), an N-type buried layer (hereinafter referred to as “NBL”), a well (hereinafter referred to as “WL”), and a Schottky diode portion (hereinafter referred to as “SD”).

The substrate SUB may be a base component that forms the structure of the semiconductor integrated circuit device SICD. As some examples, the substrate SUB may be a silicon-based P-type substrate. In other words, the substrate SUB may include a P-type substrate P-sub implemented in P-type, but embodiments of the present disclosure are not limited thereto. A variety of material layers (e.g., NBL) and the like may be deposited on the substrate SUB.

The buried layer NBL may include a region implemented in N-type. In other words, the buried layer NBL may be an N-type doped region. The buried layer NBL may be disposed on one side of the substrate SUB. For example, the buried layer NBL may be deposited on top of the substrate SUB as shown in FIGS. 2a and 2b, but embodiments of the present disclosure are not limited thereto. The buried layer NBL has a high electron density and can transmit electrical signals or provide electrical isolation between the substrate SUB and upper semiconductor layers (e.g., the well WL and the Schottky diode portion SD).

The well WL may include a semiconductor region. For example, the well WL may include an N-type semiconductor region HV-Nwell, but embodiments of the present disclosure are not limited thereto. The well WL may be disposed on one side of the buried layer NBL. For example, the well WL may be disposed on top of the buried layer NBL as shown in FIGS. 2a and 2b, but embodiments of the present disclosure are not limited thereto.

The Schottky diode portion SD is a diode that utilizes the rectifying action of a barrier (Schottky barrier) that forms at the contact surface of a metal and a semiconductor. Specifically, when an N-type semiconductor and a metal are connected, a Schottky barrier is produced at the contact surface of the metal and the semiconductor, and the Schottky diode portion SD is a diode that utilizes the rectifying action this Schottky barrier. The Schottky diode portion SD may also be referred to by the term Schottky barrier diode.

As some examples, the Schottky diode portion SD may include an anode (hereinafter referred to as “AN”), a guard ring (hereinafter referred to as “GR”), a poly field plate (hereinafter referred to as “PFP”), an insulator, and a cathode (hereinafter referred to as “CA”). The insulator may include a shallow trench isolation STI. In the following, the insulator will be described by being referred to as STI for convenience of description.

The anode AN is a region where current begins to flow in the Schottky diode portion SD and may be a region that forms a Schottky barrier. In this case, the anode AN may be disposed at the central portion of the Schottky diode portion SD and the semiconductor integrated circuit device SICD, as shown in FIGS. 1, 3a, and 3b. However, embodiments of the present disclosure are not limited thereto.

The poly field plate PFP may be connected to the anode AN and the guard ring GR. The poly field plate PFP may serve to regulate the electric field and improve isolation and stability between elements. In this case, the poly field plate PFP may be disposed in a structure surrounding the anode AN and the guard ring GR as shown in FIG. 1, but embodiments of the present disclosure are not limited thereto.

The insulator STI may serve to electrically isolate respective elements. As some examples, the insulator STI may be responsible for electrical isolation between the anode AN and the cathode CA. In other words, the anode AN and the cathode CA may be electrically separated via the insulator STI.

The cathode CA may serve to transmit the current generated at the anode AN to the outside. The cathode CA may be an N-type doped region of high concentration. In this case, the cathode CA may be disposed on the outermost side as a structure surrounding the anode AN, the guard ring GR, and the poly field plate PFP, as shown in FIG. 1, but embodiments of the present disclosure are not limited thereto.

The guard ring GR is a P-type silicon region and may be a configuration for improving the reverse voltage characteristic of the Schottky diode portion SD. The guard ring GR may be disposed on one side of the anode AN. The guard ring GR may also be referred to by terms such as a P-tab.

In this case, there may be no floating area present in the guard ring GR. In other words, the guard ring GR may not be in an independent state of being electrically separated from other components. That is, the guard ring GR may be connected to the anode AN and the poly field plate PFP with one node, and accordingly, no floating area may be present.

In general, Schottky diodes have a lower turn-on voltage compared to PN junction diodes, and thus have a low voltage drop characteristic in the forward state (forward operating condition) and are advantageous for high-speed operation. However, Schottky diodes have the drawbacks of having a lower BV (breakdown voltage) characteristic and a higher leakage characteristic compared to PN junction diodes in the reverse state. Accordingly, in a general case, lateral Schottky diodes have been developed in the direction of compensating for the insufficient performance by using P-type guard rings in order to compensate for the drawbacks of these reverse characteristics. However, in the case of the existing method, the current path flowing from the cathode to the anode increases with the addition of the P-type guard ring, which results in the drawback of increasing the ON-resistance RON characteristic of the semiconductor device as well.

In order to resolve this, the guard ring GR included in the Schottky diode portion SD in accordance with some embodiments of the present disclosure may include at least one slit (hereinafter referred to as “SL”) that blocks the flow of current. In this case, the slit SL may also be referred to as a gap, an opening, a penetration part, or the like. In other words, due to the slit SL included in the guard ring GR, the current flow in the Schottky diode portion SD of the present disclosure can be blocked in part.

As some examples, the slit SL may be formed on one side of the guard ring GR.

For example, the slit SL may be disposed in at least one of a plurality of regions forming the guard ring GR. In this case, the slit SL may be formed to penetrate at least a portion of the plurality of regions of the guard ring GR.

Described more specifically by taking FIG. 2 as an example, the guard ring GR may include a plurality of guard ring parts (hereinafter referred to as “GP”). In other words, the guard ring GR may include a first guard ring part GP1 through a third guard ring part GP3. In this case, the first guard ring part GP1 and the third guard ring part GP3 may be disposed in positions facing each other. That is, the first guard ring part GP1 and the third guard ring part GP3 may be formed in opposing positions. The guard ring GR is described as including the first guard ring part GP1 through the third guard ring part GP3 for convenience of description, but as a matter of course, the guard ring GR may include a plurality of guard ring parts in addition to the first guard ring part GP1 through the third guard ring part GP3, as shown in FIG. 2.

In this case, slits SL1 and SL2 may be formed between the respective guard ring parts GP1 to GP3, etc., as shown in FIG. 2. FIG. 2 illustrates by way of example that the slits SL1 and SL2 are formed between the first guard ring part GP1 and the second guard ring part GP2, between the third guard ring part GP3 and the second guard ring part GP2, and the like, but embodiments of the present disclosure are not limited thereto. FIG. 2 illustrates that a total of eight slits SL are formed, but as a matter of course, embodiments of the present disclosure are not limited thereto.

In this case, each guard ring part GP1 to GP3, etc., may be partitioned via the slits SL1 and SL2. That is, each guard ring part GP1 to GP3, etc., may be distinguished based on the presence or absence of the slits SL1 and SL2.

As some examples, the slits SL1 and SL2 may be formed between adjacent faces of each guard ring part GP1 to GP3, etc. That is, the slits SL1 and SL2 may be formed between a first face P1 of the first guard ring part GP1 and a second face P2 of the second guard ring part GP2 and/or between a third face P3 of the third guard ring part GP3 and a fourth face P4 of the second guard ring part GP2. In other words, the guard ring GR may include a first slit SL1 formed between the first face P1 of the first guard ring part GP1 and the second face P2 of the second guard ring part GP2, and a second slit SL2 formed between the third face P3 of the third guard ring part GP3 and the fourth face P4 of the second guard ring part GP2. In this case, the first face P1 may be the face closest to the second guard ring part GP2 among a plurality of faces of the first guard ring part GP1, the second face P2 may be the face closest to the first guard ring part GP1 among a plurality of faces of the second guard ring part GP2, the third face P3 may be the face closest to the second guard ring part GP2 among a plurality of faces of the third guard ring part GP3, and the fourth face P4 may be the face closest to the third guard ring part GP3 among the plurality of faces of the second guard ring part GP2.

In this case, the first slit SL1 and the second slit SL2 may be disposed in positions facing each other. In other words, the first slit SL1 and the second slit SL2 may be disposed in opposing positions. That is, the first face P1 corresponding to the first slit SL1 may be parallel to the third face P3 corresponding to the second slit SL2, and the second face P2 corresponding to the first slit SL1 may be parallel to the fourth face P4 corresponding to the second slit SL2. However, embodiments of the present disclosure are not limited thereto.

Meanwhile, the size of the slits SL1 and SL2 may be determined according to predetermined criteria.

For example, the size of the slits SL1 and SL2 may be smaller than an inner separation distance (hereinafter referred to as “ID”) of the guard ring GR.

For example, the size of the slits SL1 and SL2 may be smaller than a separation distance ID between a fifth face P5 of the first guard ring part GP1 disposed on one side of the first face P1 and a sixth face P6 of the third guard ring part GP3 disposed on one side of the third face P3. In other words, the inner separation distance ID of the guard ring GR may include the distance between the fifth face P5 and the sixth face P6. In this case, the fifth face P5 and the sixth face P6 may be faces disposed in positions facing each other. In other words, the fifth face P5 and the sixth face P6 may be faces formed at opposing positions.

In this case, the size of the slits SL1 and SL2 may have an optimized value by taking into account the doping concentration of the guard ring GR, the junction depth, and the doping concentration of the well WL. That is, as the size of the slits SL1 and SL2 increases, the ON-resistance RON of the Schottky diode portion SD is further improved. However, if the size of the slits SL1 and SL2 increases excessively, there is a risk that the BV (breakdown voltage) characteristic will decrease and the leakage current characteristic will increase. Therefore, the size of the slits SL1 and SL2 formed in the guard ring GR in accordance with some embodiments of the present disclosure may have an optimal value that comprehensively takes these points into consideration. As one example, the size of the slits SL1 and SL2 may be 0.2 μm or more and 2 μm or less, but embodiments of the present disclosure are not limited thereto.

With these slits SL1 and SL2, the Schottky diode portion SD in accordance with some embodiments of the present disclosure may have a reduced current path between the anode AN and the cathode CA, and thus, have the effect of improving the ON-resistance RON of the Schottky diode portion SD.

Described by taking FIGS. 3a and 3b as an example, FIG. 3a shows a side view of a cut section of portion “A” in FIG. 1, and FIG. 3b shows a side view of a cut section of portion “B” in FIG. 1. In this case, the portion “A” in FIG. 1 refers to a portion where the slit SL is formed in the guard ring GR, and the portion “B” in FIG. 1 refers to a portion where the slit SL is not formed in the guard ring GR. Accordingly, FIG. 3a shows the guard ring GR, but FIG. 3b does not show the guard ring GR. As illustrated in FIG. 3a, in the case of the portion where the slit SL is not formed, the current path is shown to be increased by the guard ring GR. On the contrary, as illustrated in FIG. 3b, in the case of the portion where the slit SL is formed, the current path is shown to be reduced by the guard ring GR compared to FIG. 3a. As such, the Schottky diode portion SD in accordance with some embodiments of the present disclosure may have a reduced current path in part between the anode AN and the cathode CA due to the slits SL, and thus, have the effect of improving the ON-resistance RON of the Schottky diode portion SD.

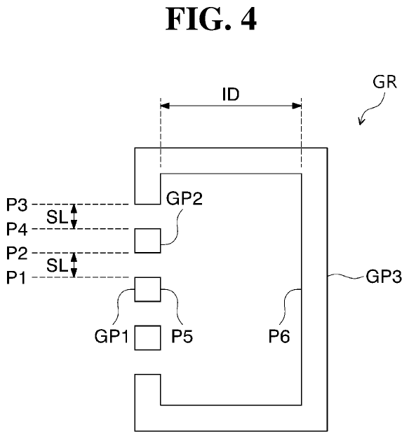

FIG. 4 is a diagram for describing a guard ring in accordance with some other embodiments of the present disclosure.

Referring to FIG. 4, a guard ring GR in accordance with some embodiments of the present disclosure may include at least one slit SL that blocks the flow of current.

In this case, FIG. 4 illustrates the guard ring GR with slits SL formed only in one side region (left region) of the guard ring GR, unlike the guard ring GR shown in FIGS. 1 and 2. However, embodiments of the present disclosure are not limited to this, and the slits SL may be formed only in the right region of the guard ring GR as well.

As some examples, the slits SL may be formed on one side, for example, in the left region of the guard ring GR. In this case, the slits SL may be formed to penetrate at least a portion of the left region of the guard ring GR.

The guard ring GR may include a plurality of guard ring parts GP. In other words, the guard ring GR may include a first guard ring part GP1 through a third guard ring part GP3. The guard ring GR is described as including the first guard ring part GP1 through the third guard ring part GP3 for convenience of description, but as a matter of course, the guard ring GR may include a plurality of guard ring parts in addition to the first guard ring part GP1 through the third guard ring part GP3, as shown in FIG. 4.

In this case, the slits SL may be formed between the respective guard ring parts GP1 to GP3, etc., as shown in FIG. 4. FIG. 4 illustrates by way of example that the slits SL are formed between the first guard ring part GP1 and the second guard ring part GP2, between the second guard ring part GP2 and the third guard ring part GP3, and the like, but embodiments of the present disclosure are not limited thereto. FIG. 4 illustrates that a total of three slits SL are formed, but as a matter of course, embodiments of the present disclosure are not limited thereto.

In this case, each guard ring part GP1 to GP3, etc., may be partitioned via the slits SL. That is, each guard ring part GP1 to GP3, etc., may be distinguished based on the presence or absence of the slits SL.

As some examples, the slits SL may be formed between adjacent faces of each guard ring part GP1 to GP3, etc. That is, the slits SL may be formed between a first face P1 of the first guard ring part GP1 and a second face P2 of the second guard ring part GP2 and/or between a third face P3 of the third guard ring part GP3 and a fourth face P4 of the second guard ring part GP2. In other words, the guard ring GR may include at least one slit SL formed between the first face P1 of the first guard ring part GP1 and the second face P2 of the second guard ring part GP2 and/or between the third face P3 of the third guard ring part GP3 and the fourth face P4 of the second guard ring part GP2. In this case, the first face P1 may be the face closest to the second guard ring part GP2 among a plurality of faces of the first guard ring part GP1, the second face P2 may be the face closest to the first guard ring part GP1 among a plurality of faces of the second guard ring part GP2, the third face P3 may be the face closest to the second guard ring part GP2 among a plurality of faces of the third guard ring part GP3, and the fourth face P4 may be the face closest to the third guard ring part GP3 among the plurality of faces of the second guard ring part GP2.

Meanwhile, the size of the slits SL may be determined according to predetermined criteria. For example, the size of the slits SL may be smaller than an inner separation distance ID of the guard ring GR.

For example, the size of the slits SL may be smaller than a separation distance ID between a fifth face P5 of the first guard ring part GP1 disposed on one side of the first face P1 and a sixth face P6 of the third guard ring part GP3 disposed on one side of the third face P3. In other words, the inner separation distance ID of the guard ring GR may include the distance between the fifth face P5 and the sixth face P6. In this case, the fifth face P5 and the sixth face P6 may be faces disposed in positions facing each other. In other words, the fifth face P5 and the sixth face P6 may be faces formed at opposing positions.

In this case, the size of the slits SL may have an optimized value by taking into account the doping concentration of the guard ring GR, the junction depth, and the doping concentration of the well WL, as described above. As one example, the size of the slits SL may be 0.2 μm or more and 2 μm or less, but embodiments of the present disclosure are not limited thereto.

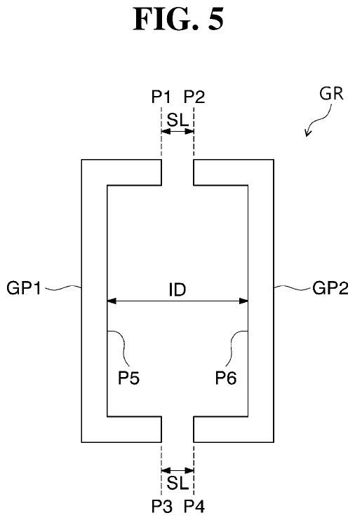

FIG. 5 is a diagram for describing a guard ring in accordance with yet some other embodiments of the present disclosure.

Referring to FIG. 5, a guard ring GR in accordance with some embodiments of the present disclosure may include at least one slit SL that blocks the flow of current.

In this case, FIG. 5 illustrates the guard ring GR with slits SL formed in an upper region and a lower region of the guard ring GR, unlike the guard ring GR shown in FIGS. 1 and 2. However, embodiments of the present disclosure are not limited to this, and the slits SL may be formed only in one of the upper region and the lower region of the guard ring GR as well.

As some examples, the slits SL may be formed on one side, for example, in the upper region and the lower region of the guard ring GR. In this case, the slits SL may be formed to penetrate at least a portion of the upper region and the lower region of the guard ring GR.

The guard ring GR may include a plurality of guard ring parts GP. In other words, the guard ring GR may include a first guard ring part GP1 and a second guard ring part GP2.

In this case, the slits SL may be formed between the respective guard ring parts GP1 and GP2, as shown in FIG. 5. FIG. 5 illustrates by way of example that the slits SL are formed between the first guard ring part GP1 and the second guard ring part GP2. FIG. 5 illustrates that a total of two slits SL are formed, but as a matter of course, embodiments of the present disclosure are not limited thereto.

In this case, each guard ring part GP1 and GP2 may be partitioned via the slits SL. That is, each guard ring part GP1 and GP2 may be distinguished based on the presence or absence of the slits SL.

As some examples, the slits SL may be formed between adjacent faces of each guard ring part GP1 and GP2. That is, the slits SL may be formed between a first face P1 of the first guard ring part GP1 and a second face P2 of the second guard ring part GP2 and/or between a third face P3 of the first guard ring part GP1 and a fourth face P4 of the second guard ring part GP2. In other words, the guard ring GR may include at least one slit SL formed between the first face P1 of the first guard ring part GP1 and the second face P2 of the second guard ring part GP2 and/or between the third face P3 of the first guard ring part GP1 and the fourth face P4 of the second guard ring part GP2. In this case, the first face P1 may be a face adjacent to the second guard ring part GP2 among a plurality of faces of the first guard ring part GP1, the second face P2 may be a face adjacent to the first guard ring part GP1 among a plurality of faces of the second guard ring part GP2, the third face P3 may be a face adjacent to the second guard ring part GP2 among a plurality of faces of the third guard ring part GP3, and the fourth face P4 may be a face adjacent to the third guard ring part GP3 among the plurality of faces of the second guard ring part GP2.

Meanwhile, the size of the slits SL may be determined according to predetermined criteria. For example, the size of the slits SL may be smaller than an inner separation distance ID of the guard ring GR.

For example, the size of the slits SL may be smaller than a separation distance ID between a fifth face P5 of the first guard ring part GP1 disposed on one side of the first face P1 and a sixth face P6 of the second guard ring part GP2 disposed on one side of the second face P2. In other words, the inner separation distance ID of the guard ring GR may include the distance between the fifth face P5 and the sixth face P6. In this case, the fifth face P5 and the sixth face P6 may be faces disposed in positions facing each other. In other words, the fifth face P5 and the sixth face P6 may be faces formed at opposing positions.

In this case, the size of the slits SL may have an optimized value by taking into account the doping concentration of the guard ring GR, the junction depth, and the doping concentration of the well WL, as described above. As one example, the size of the slits SL may be 0.2 μm or more and 2 μm or less, but embodiments of the present disclosure are not limited thereto.

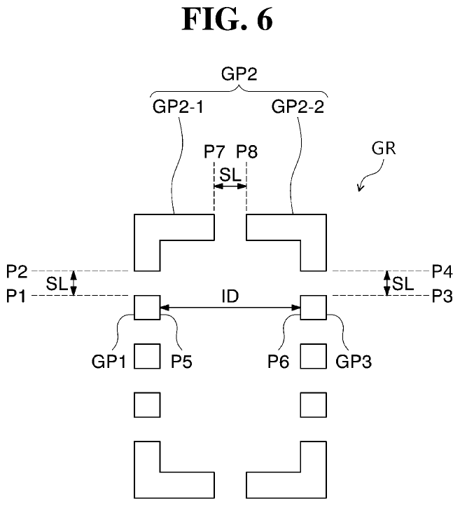

FIG. 6 is a diagram for describing a guard ring in accordance with yet some other embodiments of the present disclosure.

Referring to FIG. 6, a guard ring GR in accordance with some embodiments of the present disclosure may include at least one slit SL that blocks the flow of current.

In this case, FIG. 6 illustrates the guard ring GR with slits SL formed in all of the upper region, the lower region, the left region, and the right region of the guard ring GR, unlike the guard ring GR shown in FIGS. 1 and 2. However, embodiments of the present disclosure are not limited to this, and the slits SL may be omitted in any one of the upper region, the lower region, the left region, and the right region of the guard ring GR.

As some examples, the slits SL may be formed on one side, for example, in the upper region, the lower region, the left region, and the right region of the guard ring GR. In this case, the slits SL may be formed to penetrate at least a portion of each region of the guard ring GR.

The guard ring GR may include a plurality of guard ring parts GP. In other words, the guard ring GR may include a first guard ring part GP1 through a third guard ring part GP3. The guard ring GR is described as including the first guard ring part GP1 through the third guard ring part GP3 for convenience of description, but as a matter of course, the guard ring GR may include a plurality of guard ring parts in addition to the first guard ring part GP1 through the third guard ring part GP3, as shown in FIG. 6.

In this case, the second guard ring part GP2 may be designed to be divided, as shown in FIG. 6. In other words, the second guard ring part GP2 may include a (2-1)-th guard ring part GP2-1 and a (2-2)-th guard ring part GP2-2. Slits SL may be formed between the (2-1)-th guard ring part GP2-1 and the (2-2)-th guard ring part GP2-2.

The slits SL may be formed inside each guard ring part GP1 to GP3, etc., or between each guard ring part GP1 to GP3, etc. FIG. 6 illustrates by way of example that the slits SL are formed between the first guard ring part GP1 and the (2-1)-th guard ring part GP2-1, between the (2-1)-th guard ring part GP2-1 and the (2-2)-th guard ring part GP2-2, between the (2-2)-th guard ring part GP2-2 and the third guard ring part GP3, and the like, but embodiments of the present disclosure are not limited thereto. FIG. 6 illustrates that a total of ten slits SL are formed, but as a matter of course, embodiments of the present disclosure are not limited thereto.

In this case, each guard ring part GP1 to GP3, etc., may be partitioned via the slits SL. That is, each guard ring part GP1 to GP3, etc., may be distinguished based on the presence or absence of the slits SL.

As some examples, the slits SL may be formed between adjacent faces of each guard ring part GP1 to GP3, etc. That is, the slits SL may be formed between a first face P1 of the first guard ring part GP1 and a second face P2 of the (2-1)-th guard ring part GP2-1, between a third face P3 of the third guard ring part GP3 and a fourth face P4 of the (2-2)-th guard ring part GP2-2, and/or between a seventh face P7 of the (2-1)-th guard ring part GP2-1 and an eighth face P8 of the (2-2)-th guard ring part GP2-2. In other words, the guard ring GR may include at least one slit SL formed between the first face P1 of the first guard ring part GP1 and the second face P2 of the second guard ring part GP2, between the third face P3 of the third guard ring part GP3 and the fourth face P4 of the second guard ring part GP2, and/or between the seventh face P7 of the (2-1)-th guard ring part GP2-1 and the eighth face P8 of the (2-2)-th guard ring part GP2-2. In this case, the first face P1 may be the face closest to the (2-1)-th guard ring part GP2-1 among a plurality of faces of the first guard ring part GP1, the second face P2 may be the face closest to the first guard ring part GP1 among a plurality of faces of the (2-1)-th guard ring part GP2-1, the third face P3 may be the face closest to the (2-2)-th guard ring part GP2-2 among a plurality of faces of the third guard ring part GP3, the fourth face P4 may be the face closest to the third guard ring part GP3 among a plurality of faces of the (2-2)-th guard ring part GP2-2, the seventh face P7 may be the face closest to the (2-2)-th guard ring part GP2-2 among the plurality of faces of the (2-1)-th guard ring part GP2-1, and the eighth face P8 may be the face closest to the (2-1)-th guard ring part GP2-1 among the plurality of faces of the (2-2)-th guard ring part GP2-2.

Meanwhile, the size of the slits SL may be determined according to predetermined criteria. For example, the size of the slits SL may be smaller than an inner separation distance ID of the guard ring GR.

For example, the size of the slits SL may be smaller than a separation distance ID between a fifth face P5 of the first guard ring part GP1 disposed on one side of the first face P1 and a sixth face P6 of the third guard ring part GP3 disposed on one side of the third face P3. In other words, the inner separation distance ID of the guard ring GR may include the distance between the fifth face P5 and the sixth face P6. In this case, the fifth face P5 and the sixth face P6 may be faces disposed in positions facing each other. In other words, the fifth face P5 and the sixth face P6 may be faces formed at opposing positions.

In this case, the size of the slits SL may have an optimized value by taking into account the doping concentration of the guard ring GR, the junction depth, and the doping concentration of the well WL, as described above. As one example, the size of the slits SL may be 0.2 μm or more and 2 μm or less, but embodiments of the present disclosure are not limited thereto.

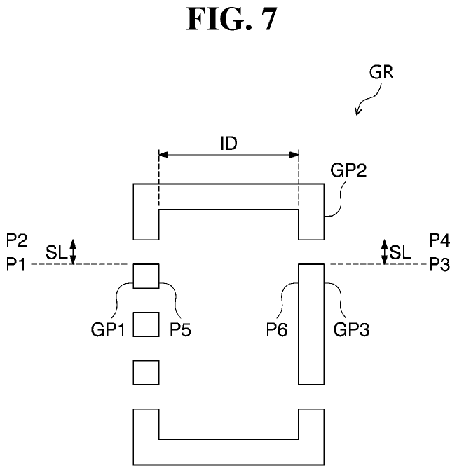

FIG. 7 is a diagram for describing a guard ring in accordance with yet some other embodiments of the present disclosure.

Referring to FIG. 7, a guard ring GR in accordance with some embodiments of the present disclosure may include at least one slit SL that blocks the flow of current.

In this case, FIG. 7 illustrates the guard ring GR with different numbers of slits SL formed in the left region and the right region thereof, unlike the guard ring GR shown in FIGS. 1 and 2.

As some examples, the slits SL may be formed on one side, for example, in the left region and/or the right region of the guard ring GR. In this case, the slits SL may be formed to penetrate at least a portion of the left region and/or the right region of the guard ring GR.

The guard ring GR may include a plurality of guard ring parts GP. In other words, the guard ring GR may include a first guard ring part GP1 through a third guard ring part GP3. The guard ring GR is described as including the first guard ring part GP1 through the third guard ring part GP3 for convenience of description, but as a matter of course, the guard ring GR may include a plurality of guard ring parts in addition to the first guard ring part GP1 through the third guard ring part GP3, as shown in FIG. 7.

In this case, the slits SL may be formed between the respective guard ring parts GP1 to GP3, etc., as shown in FIG. 7. FIG. 7 illustrates by way of example that the slits SL are formed between the first guard ring part GP1 and the second guard ring part GP2, between the second guard ring part GP2 and the third guard ring part GP3, and the like, but embodiments of the present disclosure are not limited thereto. FIG. 7 illustrates that a total of six slits SL are formed, but as a matter of course, embodiments of the present disclosure are not limited thereto.

In this case, each guard ring part GP1 to GP3, etc., may be partitioned via the slits SL. That is, each guard ring part GP1 to GP3, etc., may be distinguished based on the presence or absence of the slits SL.

As some examples, the slits SL may be formed between adjacent faces of each guard ring part GP1 to GP3, etc. That is, the slits SL may be formed between a first face P1 of the first guard ring part GP1 and a second face P2 of the second guard ring part GP2 and/or between a third face P3 of the third guard ring part GP3 and a fourth face P4 of the second guard ring part GP2. In other words, the guard ring GR may include at least one slit SL formed between the first face P1 of the first guard ring part GP1 and the second face P2 of the second guard ring part GP2 and/or between the third face P3 of the third guard ring part GP3 and the fourth face P4 of the second guard ring part GP2. In this case, the first face P1 may be the face closest to the second guard ring part GP2 among a plurality of faces of the first guard ring part GP1, the second face P2 may be the face closest to the first guard ring part GP1 among a plurality of faces of the second guard ring part GP2, the third face P3 may be the face closest to the second guard ring part GP2 among a plurality of faces of the third guard ring part GP3, and the fourth face P4 may be the face closest to the third guard ring part GP3 among the plurality of faces of the second guard ring part GP2.

Meanwhile, the size of the slits SL may be determined according to predetermined criteria. For example, the size of the slits SL may be smaller than an inner separation distance ID of the guard ring GR.

For example, the size of the slits SL may be smaller than a separation distance ID between a fifth face P5 of the first guard ring part GP1 disposed on one side of the first face P1 and a sixth face P6 of the third guard ring part GP3 disposed on one side of the third face P3. In other words, the inner separation distance ID of the guard ring GR may include the distance between the fifth face P5 and the sixth face P6. In this case, the fifth face P5 and the sixth face P6 may be faces disposed in positions facing each other.

In this case, the size of the slits SL may have an optimized value by taking into account the doping concentration of the guard ring GR, the junction depth, and the doping concentration of the well WL, as described above. As one example, the size of the slits SL may be 0.2 μm or more and 2 μm or less, but embodiments of the present disclosure are not limited thereto.

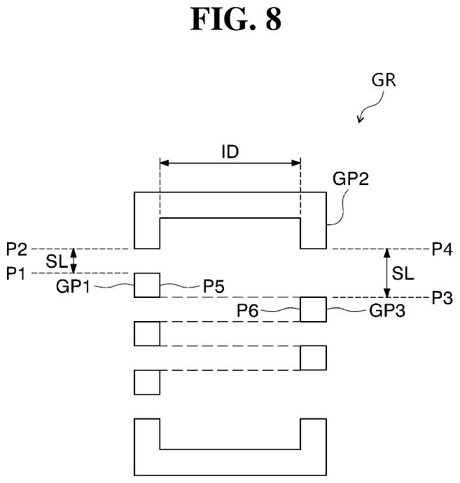

FIG. 8 is a diagram for describing a guard ring in accordance with yet some other embodiments of the present disclosure.

Referring to FIG. 8, a guard ring GR in accordance with some embodiments of the present disclosure may include at least one slit SL that blocks the flow of current.

In this case, FIG. 8 illustrates a guard ring GR in which the slits SL formed in the left region and the right region thereof do not face each other, i.e., are formed in a staggered arrangement, unlike the guard ring GR shown in FIGS. 1 and 2.

As some examples, the slits SL may be formed on one side, for example, in the left region and/or the right region of the guard ring GR. In this case, the slits SL may be formed to penetrate at least a portion of the left region and/or the right region of the guard ring GR.

The guard ring GR may include a plurality of guard ring parts GP. In other words, the guard ring GR may include a first guard ring part GP1 through a third guard ring part GP3. The guard ring GR is described as including the first guard ring part GP1 through the third guard ring part GP3 for convenience of description, but as a matter of course, the guard ring GR may include a plurality of guard ring parts in addition to the first guard ring part GP1 through the third guard ring part GP3, as shown in FIG. 8.

In this case, the slits SL may be formed between the respective guard ring parts GP1 to GP3, etc., as shown in FIG. 8. FIG. 8 illustrates by way of example that the slits SL are formed between the first guard ring part GP1 and the second guard ring part GP2, between the second guard ring part GP2 and the third guard ring part GP3, and the like, but embodiments of the present disclosure are not limited thereto. FIG. 8 illustrates that a total of seven slits SL are formed, but as a matter of course, embodiments of the present disclosure are not limited thereto.

In this case, each guard ring part GP1 to GP3, etc., may be partitioned via the slits SL. That is, each guard ring part GP1 to GP3, etc., may be distinguished based on the presence or absence of the slits SL.

As some examples, the slits SL may be formed between adjacent faces of each guard ring part GP1 to GP3, etc. That is, the slits SL may be formed between a first face P1 of the first guard ring part GP1 and a second face P2 of the second guard ring part GP2 and/or between a third face P3 of the third guard ring part GP3 and a fourth face P4 of the second guard ring part GP2. In other words, the guard ring GR may include at least one slit SL formed between the first face P1 of the first guard ring part GP1 and the second face P2 of the second guard ring part GP2 and/or between the third face P3 of the third guard ring part GP3 and the fourth face P4 of the second guard ring part GP2. In this case, the first face P1 may be the face closest to the second guard ring part GP2 among a plurality of faces of the first guard ring part GP1, the second face P2 may be the face closest to the first guard ring part GP1 among a plurality of faces of the second guard ring part GP2, the third face P3 may be the face closest to the second guard ring part GP2 among a plurality of faces of the third guard ring part GP3, and the fourth face P4 may be the face closest to the third guard ring part GP3 among the plurality of faces of the second guard ring part GP2.

Meanwhile, the size of the slits SL may be determined according to predetermined criteria. For example, the size of the slits SL may be smaller than an inner separation distance ID of the guard ring GR.

For example, the size of the slits SL may be smaller than a separation distance ID between a fifth face P5 of the first guard ring part GP1 disposed on one side of the first face P1 and a sixth face P6 of the third guard ring part GP3 disposed on one side of the third face P3. In this case, the separation distance ID shown in FIG. 8 may include the vertical distance between the fifth face P5 and the sixth face P6. In this case, the fifth face P5 and the sixth face P6 may not be disposed in positions facing each other but may be arranged to stagger each other, unlike what is shown in FIGS. 1 and 2.

In this case, the size of the slits SL may have an optimized value by taking into account the doping concentration of the guard ring GR, the junction depth, and the doping concentration of the well WL, as described above. As one example, the size of the slits SL may be 0.2 μm or more and 2 μm or less, but embodiments of the present disclosure are not limited thereto.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. A semiconductor integrated circuit device comprising:
a substrate;
a buried layer disposed on one side of the substrate;
a well including a semiconductor region disposed on one side of the buried layer; and
a Schottky diode portion disposed on one side of the well,
wherein the Schottky diode portion comprises an anode, a guard ring electrically connected with the anode, and a poly field plate electrically connected with the anode and the guard ring, and
the guard ring comprises at least one slit configured to block a flow of current.

2. The semiconductor integrated circuit device of claim 1, wherein the slit is formed to penetrate at least one region of the guard ring.

3. The semiconductor integrated circuit device of claim 2, wherein the guard ring comprises a first guard ring part through a third guard ring part, and
the first guard ring part and the third guard ring part are arranged to face each other.

4. The semiconductor integrated circuit device of claim 3, wherein the slit is formed in at least one of between the first guard ring part and the second guard ring part and between the third guard ring part and the second guard ring part.

5. The semiconductor integrated circuit device of claim 4, wherein the slit is formed in at least one of between adjacent faces of the first guard ring part and the second guard ring part and between adjacent faces of the third guard ring part and the second guard ring part.

6. The semiconductor integrated circuit device of claim 5, wherein the slit comprises at least one of a first slit formed between a first face of the first guard ring part and a second face of the second guard ring part and a second slit formed between a third face of the third guard ring part and a fourth face of the second guard ring part, and
wherein the first face comprises a face closest to the second guard ring part among a plurality of faces of the first guard ring part,
the second face comprises a face closest to the first guard ring part among a plurality of faces of the second guard ring part,
the third face comprises a face closest to the second guard ring part among a plurality of faces of the third guard ring part, and
the fourth face comprises a face closest to the third guard ring part among the plurality of faces of the second guard ring part.

7. The semiconductor integrated circuit device of claim 6, wherein the first slit and the second slit are disposed in positions facing each other.

8. The semiconductor integrated circuit device of claim 6, wherein the slit has a size smaller than a separation distance between a fifth face of the first guard ring part disposed on one side of the first face and a sixth face of the third guard ring part disposed on one side of the third face, and
the fifth face and the sixth face are disposed in positions facing each other.

9. The semiconductor integrated circuit device of claim 8, wherein the size of the slit is 0.2 μm or more and 2 μm or less.

10. The semiconductor integrated circuit device of claim 1, wherein the Schottky diode portion further comprises:
a cathode disposed to surround the anode, the guard ring, and the poly field plate; and
an insulator configured to electrically separate the anode and the cathode, and
wherein the insulator comprises a shallow trench isolation (STI).

11. A Schottky diode portion disposed on one side of a well including a semiconductor region, the Schottky diode portion comprising:
an anode;
a guard ring electrically connected with the anode; and
a poly field plate electrically connected with the anode and the guard ring,
wherein the guard ring comprises at least one slit configured to block a flow of current.

12. The Schottky diode portion of claim 11, wherein the slit is formed to penetrate at least one region of the guard ring.

13. The Schottky diode portion of claim 12, wherein the guard ring comprises a first guard ring part through a third guard ring part, and
the first guard ring part and the third guard ring part are arranged to face each other.

14. The Schottky diode portion of claim 13, wherein the slit is formed in at least one of between the first guard ring part and the second guard ring part and between the third guard ring part and the second guard ring part.

15. The Schottky diode portion of claim 14, wherein the slit is formed in at least one of between adjacent faces of the first guard ring part and the second guard ring part and between adjacent faces of the third guard ring part and the second guard ring part.

16. The Schottky diode portion of claim 15, wherein the slit comprises at least one of a first slit formed between a first face of the first guard ring part and a second face of the second guard ring part and a second slit formed between a third face of the third guard ring part and a fourth face of the second guard ring part, and
wherein the first face comprises a face closest to the second guard ring part among a plurality of faces of the first guard ring part,
the second face comprises a face closest to the first guard ring part among a plurality of faces of the second guard ring part,
the third face comprises a face closest to the second guard ring part among a plurality of faces of the third guard ring part, and
the fourth face comprises a face closest to the third guard ring part among the plurality of faces of the second guard ring part.

17. The Schottky diode portion of claim 16, wherein the first slit and the second slit are disposed in positions facing each other.

18. The Schottky diode portion of claim 16, wherein the slit has a size smaller than a separation distance between a fifth face of the first guard ring part disposed on one side of the first face and a sixth face of the third guard ring part disposed on one side of the third face, and
the fifth face and the sixth face are disposed in positions facing each other.

19. The Schottky diode portion of claim 18, wherein the size of the slit is 0.2 μm or more and 2 μm or less.

20. The Schottky diode portion of claim 11, further comprising:
a cathode disposed to surround the anode, the guard ring, and the poly field plate; and
an insulator configured to electrically separate the anode and the cathode, and
wherein the insulator comprises a shallow trench isolation (STI).
